(19) United States
(12) Patent Application Publication
(10) Pub. No.: US 2026/0094790 A1
(43) Pub. Date: Apr. 2, 2026

(54) SUBSTRATE PROCESSING APPARATUS

(71) Applicant: Samsung Electronics Co., Ltd., Suwon-si (KR)

(72) Inventors: Yunjae LEE, Suwon-si (KR); Minju KIM, Suwon-si (KR); Daeyoung AHN, Suwon-si (KR); Sungyong LIM, Suwon-si (KR); Sungwon CHO, Suwon-si (KR)

(21) Appl. No.: 19/051,390

(22) Filed: Feb. 12, 2025

(30) Foreign Application Priority Data
Oct. 2, 2024 (KR) 10-2024-0133718

(51) Int. Cl. H01J 37/32

(52) U.S. Cl. CPC H01J 37/32449; H01J 37/32853; H01J 2237/3341; H01J 2237/3346

(57) ABSTRACT

According to some embodiments of the present disclosure, a substrate processing apparatus includes a chamber including a substrate processing space, a supporter inside the chamber and configured to support a substrate; an etching gas provider configured to provide an etching gas to the substrate processing space, wherein the etching gas includes radicals and/or a recombination gas formed by recombining the radicals, a processing gas provider configured to provide a processing gas to the substrate processing space, and a controller configured to control the substrate processing apparatus to perform a cycle including processing the substrate is processed with the etching gas to form an etching byproduct, and processing the substrate with the processing gas while the etching byproduct is present in the substrate processing space.

### CROSS-REFERENCE TO RELATED APPLICATION

This application claims benefit of priority under 35 U.S.C. § 119 to Korean Patent Application No. 10-2024-0133718 filed on Oct. 2, 2024 in the Korean Intellectual Property Office, the disclosure of which is incorporated herein by reference in its entirety.

### FIELD

The present disclosure relates to a substrate processing apparatus.

### BACKGROUND

As a technology for integrated circuits with high density elements and high performance, fin field-effect transistors (FinFETs) and nanosheet field-effect transistors have been introduced. The FinFET includes channel layers whose at least three surfaces are surrounded by gate structures and has vertical fin structures that are arranged in one or more horizontal directions. As the nanosheet FET, products such as a gate-all-around (GAA) transistor or a multi-bridge channel (MBC) transistor have been known. The nanosheet FET includes one or more nanosheet channel layers that are vertically stacked on a substrate and gate structures surrounding each nanosheet channel layer.

The nanosheet channel layers that are vertically stacked on the substrate may be manufactured by alternately depositing sacrificial layers and the nanosheet channel layers on the substrate and then etching the sacrificial layers. The sacrificial layer may be etched with at least one of radicals and/or gases. An etching method using radicals may increase overall process speed, but damage components other than the sacrificial layer due to high reactivity of the radicals. In addition, an etching method using gas may have high selectivity for etching only the sacrificial layer, but decrease the overall process speed.

### SUMMARY

The present disclosure provides a substrate processing apparatus capable of improving overall process speed while maintaining high etching selectivity.

Objects of the present disclosure are not limited to the above-mentioned objects. That is, other objects that are not mentioned may be obviously understood by those skilled in the art from the following description.

According to an aspect of the present disclosure, a substrate processing apparatus includes a chamber including a substrate processing space, a supporter inside the chamber and configured to support a substrate, an etching gas provider configured to provide an etching gas to the substrate processing space, wherein the etching gas includes radicals and/or a recombination gas formed by recombining radicals, a processing gas provider configured to provide a processing gas to the substrate processing space, and a controller configured to control the substrate processing apparatus to perform a cycle including processing the substrate with the etching gas to form an etching byproduct, and processing the substrate with the processing gas while the etching byproduct is present in the substrate processing space.

According to another aspect of the present disclosure, a substrate processing apparatus includes a chamber including a substrate processing space, a supporter inside the chamber and configured to support a substrate, an etching gas provider configured to provide an etching gas to the substrate processing space, wherein the etching gas includes radicals and/or a recombination gas formed by recombining the radicals, a processing gas provider configured to provide a processing gas to the substrate processing space, and a controller configured to control the substrate processing apparatus to perform a cycle including processing the substrate with the etching gas, and processing the substrate with the processing gas without performing a purge between the steps of processing the substrate with the etching gas and processing the substrate with the processing gas.

According to still another aspect of the present disclosure, a substrate processing apparatus includes a chamber including a substrate processing space, a supporter inside the chamber and configured to support a substrate, an etching gas provider configured to provide an etching gas to the substrate processing space, wherein the etching gas includes radicals and/or a recombination gas formed by recombining the radicals, a processing gas provider configured to provide a processing gas to the substrate processing space, and a controller configured to control the substrate processing apparatus to perform a cycle including processing the substrate with the etching gas to form an etching byproduct, and processing the substrate with the processing gas while the etching byproduct is present in the substrate processing space, in which the etching gas provider includes a plasma forming space where the radicals are formed, a power supplier configured to form plasma in the plasma forming space, and a radical precursor provider configured to provide a radical precursor to the plasma forming space, a semiconductor layer including silicon germanium (SiGe) is on the substrate, the radicals include fluorine radicals (F*), the recombination gas includes a fluorine gas (F₂), and the processing gas includes at least one of fluorine gas (F₂) or germanium fluoride gas (GeF₄), and the controller is configured to control the substrate processing apparatus to process the substrate with the etching gas for a first duration of time and to process the substrate with the processing gas for a second duration of time, wherein the first duration of time is shorter than the second duration of time, perform the cycle on the substrate multiple times, and perform a purge during at least some of the cycles.

Detailed contents of other example embodiments are described in a detailed description and are illustrated in the drawings.

According to the present disclosure, it is possible to provide the substrate processing apparatus capable of improving the overall process speed while having the high etching selectivity.

The effects of the present disclosure are not limited to the above-mentioned effects, and other effects that are not mentioned may be obviously understood by those skilled in the art from the following description.

### BRIEF DESCRIPTION OF DRAWINGS

The drawings illustrated in the present disclosure are according to example embodiments, and a ratio of a width, depth, or height (or thickness) of each component is for describing the present disclosure in detail, and these ratios may be different from the actual ones. In addition, each axis in coordinate systems illustrated in the drawings may be perpendicular to each other, and a direction pointed by an arrow may be a + direction, and a direction (direction rotated by 180°) opposite to the direction pointed by an arrow may be a − direction:

FIG. 1 is a cross-sectional view schematically illustrating a substrate processing apparatus according to some embodiments of the present disclosure;

FIGS. 2 to 4 are cross-sectional views schematically illustrating a substrate and a semiconductor layer for describing a process of processing the substrate by the substrate processing apparatus according to some embodiments of the present disclosure; and

FIG. 5 is a flowchart for describing a method of performing a process of processing a substrate processing apparatus according to some embodiments of the present disclosure.

### DETAILED DESCRIPTION

Prior to the detailed description of the present disclosure, it should be noted that terms or words used in this specification and claims may not be interpreted as limited to their ordinary or dictionary meanings. In addition, the terms or words may be interpreted to have meanings and concepts that conform to the technical idea of the present disclosure based on the principle that the inventors may appropriately define the concept of terms to explain their inventions in the best way. The example embodiments described in this specification and the configurations illustrated in the drawings are merely the best example embodiments of the present disclosure and may not represent all of the technical ideas of the present disclosure. Accordingly, there may be various equivalents and modified examples that may replace the example embodiments at the time of filing of the present disclosure.

The same reference numbers or symbols described in each drawing attached to this specification may indicate parts or components that perform substantially the same function. For the convenience of description and understanding, the same reference numbers or symbols may be used in different example embodiments. In other words, even if components having the same reference numbers are illustrated in multiple drawings, all the multiple drawings may not mean an example embodiment.

When a component is described herein as being “directly above” or “adjacent to” or “in contact with” another component, it may be understood that the component is directly contact or connected to the other component, and that there is no other component between these components.

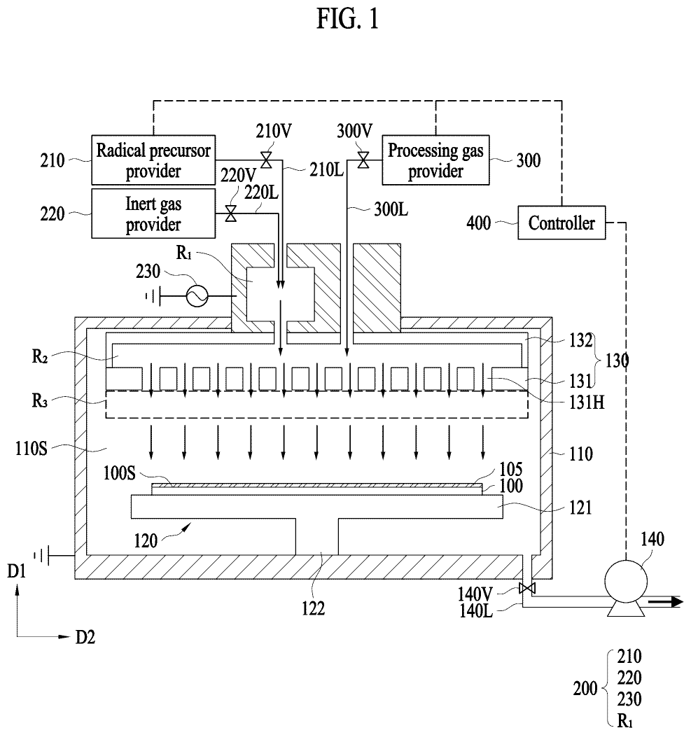

In addition, when a component is described herein as being “above” or “on” another component, it may be understood that the component exists above in a vertical direction. For example, it may be understood that the component exists higher in a +D1 direction in the drawing (FIG. 1). These components may be in direct contact or connected with each other, but it may be understood that another component exists between these components. The same applies when a component is described herein as being “above” another component. In addition, when a component is described herein as being “above” or “on” another component, it may be understood that the component exists below in a vertical direction. For example, it may be understood that the component exists lower in a −D1 direction in the drawing (FIG. 1). These components may be in direct contact or connected with each other, but it may be understood that another component exists between these components. The same applies when a component is described herein as being “below”another component.

Other similar expressions that describe the positional relationship between the components may be interpreted in the same manner as above.

In the following description, singular forms are intended to include plural forms unless the context clearly indicates otherwise. It should be further understood that the terms such as “include” or “configure” specify the presence of features, numerals, steps, operations, components, parts mentioned in the present specification, or combinations thereof, but do not preclude the presence or addition of one or more other features, numerals, steps, operations, components, parts, or combinations thereof.

In addition, in the following description, the terms such as “upper side,” “upper surface,” “lower side,” “lower surface,” “side surface,” “front surface,” and “rear surface” are expressed based on directions illustrated in the drawings and may be differently expressed when directions of corresponding targets change.

In this specification and claims, terms including ordinal numbers such as “first,” “second” may be used to distinguish between components. These ordinal numbers may be used to distinguish the same or similar components from each other, and the meaning of the terms should not be restrictively construed by the use of these ordinal numbers. As an example, components combined with these ordinal numbers should not be limited in order of use or arrangement by the ordinal numbers. If necessary, the respectively ordinal numbers may be interchangeably used.

Physical properties mentioned herein may be measured at room temperature and atmospheric pressure conditions unless specifically limited. In this specification, the room temperature is a natural temperature without artificial manipulation, and may be 10° C. to 30° C., 20° C. to 28° C., or 22° C. to 26° C., and may be, for example, 25° C.. In this specification, the atmospheric pressure is a natural pressure without artificial manipulation, and may be 700 mmHg to 800 mmHg, or 720 mmHg to 780 mmHg, and may be, for example, 760 mmHg.

Hereinafter, example embodiments according to the technical idea of the present disclosure will be described with reference to the accompanying drawings.

FIG. 1 is a cross-sectional view schematically illustrating a substrate processing apparatus 10 according to some embodiments of the present disclosure. In some embodiments, the substrate processing apparatus 10 may be an apparatus that performs etching. The substrate processing apparatus 10 may perform etching using radicals. As used herein, the term radicals refers to a plurality of radical particles. The plurality of radical particles may be comprised of a single type of radical particle or a mixture of multiple types of radical particles. The substrate processing apparatus 10 may perform etching using a gas or multiple gases. The substrate processing apparatus 10 may perform etching using both radicals and a gas or gases.

In some embodiments, the substrate processing apparatus 10 may include a chamber 110, an etching gas provider 200, a processing gas provider 300, and a controller 400.

The chamber 110 has a substrate processing space 110S. In some embodiments, the substrate processing apparatus 10 may include a supporter 120 inside the chamber 110 to support a substrate 100. The substrate processing apparatus 10 may perform etching on the substrate 100 itself or a material layer formed on the substrate 100. The material layer may be at least one of an insulating layer and a conductive layer formed on the substrate through various methods such as deposition, coating, or plating. The material layer may be a single film formed on the substrate or may be a multilayer film. In addition, the material layer may have a predetermined pattern. In some embodiments, the material layer may include a semiconductor layer 105 containing or including a compound semiconductor.

In the present specification, a first direction D1 is a direction perpendicular to a surface 100S of the substrate. In addition, a second direction D2 is a direction intersecting the first direction D1. In some embodiments, the second direction D2 is perpendicular to the first direction D1 and, in some embodiments, is a direction parallel to the surface 100S of the substrate.

In some embodiments, an outer structure of the chamber 110 may be, but is not limited to, a cylindrical, elliptical, or polygonal columnar shape. The chamber 110 may include a metal material and may be electrically grounded to block noise applied from the outside. The chamber 110 may include aluminum (Al) as the metal material.

In some embodiments, a liner (not illustrated) may be formed on an inner side of the chamber 110. The liner may protect the chamber 110 and minimize or reduce the occurrence of metal contamination due to arcing inside the chamber 110. The liner may contain or include the metal material such as aluminum (Al), a ceramic material such as alumina (Al₂O₃). For example, the liner may be, but is not limited to, a yttrium oxide (Y₂O₃) layer that is resistant to plasma.

In some embodiments, the supporter 120 may include a stage 121 on which a flat seating surface on which the substrate 100 is seated. The supporter 120 may include a support 122 supporting the stage 121.

In some embodiments, the stage 121 may allow a position of the substrate 100 seated on the seating surface to be fixed by electrostatic force. In some embodiments, the position of the substrate 100 may be fixed by a protruding fixing part (not illustrated) protruding from the stage 121, and one or more protruding fixing parts may be on the substrate 100 to correspond to a size of the substrate 100. A method of fixing the position of the substrate 100 is not particularly limited. In other words, it should be understood that many potential methods of fixing the position of the substrate 100 exist and the substrate processing apparatus 10 of the present invention is not limited to any one such method.

In some embodiments, the support 122 may contain or include a metal material such as aluminum (Al), or a ceramic material such as alumina (Al₂O₃). The support 122 may include an elevating device (not illustrated), and the support 122 may move along the first direction D1 due to the elevating device. In this way, the substrate 100 may be placed at a position suitable for etching. In some embodiments, an operation of the elevating device may be controlled by an electrical signal from the controller 400.

In some embodiments, the supporter 120 may include a heating member (not illustrated) inside the support 122 that transfers thermal energy to the stage 121. In some embodiments, the substrate processing apparatus 10 may include a heating device (not illustrated) that transfers the thermal energy to the heating member, and the heating device may be outside the chamber 110. The heating device transfers the thermal energy to the heating member, the heating member transfers the thermal energy to the stage 121, and the stage 121 that receives the thermal energy may transfer the thermal energy to the substrate 100 that is seated on the seating surface.

In some embodiments, the substrate processing apparatus 10 may include a shower head 130 that includes a first plate 131 in which at least one hole 131H communicating with the substrate processing space 110S is formed and a second plate 132 forming a distribution space R2 together with the first plate 131. In other words, the substrate processing apparatus 10 may include a shower head 130. The shower head 130 may include a first plate 131 and a second plate 132 which together may form a distribution space R2. The first plate 131 may have at least one hole 131H configured to permit matter in the distribution space R2 to move into and/or interact with the substrate processing space 110S.

In some embodiments, the shower head 130 may be spaced apart from the substrate 100 in the first direction D1. The shower head 130 may be inside the chamber 110. In some embodiments, the distribution space R2 may be a space where the radicals and/or gases are collected. The distribution space R2 may be connected to the substrate processing space 110S through at least one hole 131H. The radicals and/or gases may be uniformly emitted in a direction toward the substrate processing space 110S through at least one hole 131H through the distribution space R2.

In some embodiments, the substrate processing apparatus 10 may include a purger 140 that purges or removes the materials remaining inside the chamber 110 to the outside of the processing chamber 110. The purger 140 may include a discharge pump that forcibly discharges the materials remaining inside the chamber 110 to the outside of the processing chamber 110. The purger 140 may include a gas injector (not illustrated) that injects nitrogen (N₂) or an inert gas having relatively low reactivity with the materials remaining inside the chamber 110 into the chamber 110.

In some embodiments, the purger 140 may include a passage 140L through which the materials remaining inside the chamber 110 are discharged to the outside. The materials remaining inside the chamber 110 may be purged to the outside through the passage 140L. The discharge pump may apply pressure so that the materials remaining inside the chamber 110 may be easily discharged to the outside through the passage 140L. In addition, the purger 140 may include valves 140V that are between the passages 140L, and the operation of the discharge pump and the valve 140V may be each controlled by an electrical signal from the controller 400. The valve 140V may be opened when the purge is performed and may be closed when the purge is not performed.

In some embodiments, the substrate processing apparatus 10 may include an etching gas provider 200 that provides an etching gas to the substrate processing space 110S. The etching gas may include radicals and/or a recombination gas formed by recombining radicals that have been formed, produced, and/or provided by the etching gas provider 200. As discussed below, the etching gas provider 200 may generate radicals that move into the substrate processing space 110S, where those radicals may recombine to form the etching gas. As used herein, the term radicals refers to a plurality of radical particles. The plurality of radical particles may be comprised of a single type of radical particle or a mixture of multiple types of radical particles.

In some embodiments, the recombination gas may contain or include fluorine (F). The recombination gas may contain or include fluorine gas (F₂). The radicals may contain or include fluorine radicals (F*).

In some embodiments, the etching gas provider 200 may include a plasma forming space R1 in which the radicals are formed. At least a portion of the plasma forming space R1 may be outside the chamber 110.

In some embodiments, the etching gas provider 200 may include a power supplier 230 for forming plasma in the plasma forming space R1. The power supplier 230 may create an environment in which the plasma is formed in the plasma formation space R1 by applying radio frequency (RF) power in the form of an electromagnetic wave having a predetermined frequency and intensity. The power supplier 230 may be applied in the form of a continuous wave having an on-off cycle or in the form of a pulse.

In some embodiments, the etching gas provider 200 may include a radical precursor provider 210 that provides a radical precursor to the plasma formation space R1. The radical precursor provider 210 may include a passage 210L through which the radical precursor is provided to the plasma formation space R1. The radical precursor provider 210 may include a pump so as to easily provide the radical precursor to the plasma formation space R1, and the pump may apply pressure. Valves 210V may be between the passages 210L of the radical precursor provider 210, and the operations of the pump and the valve 210V may be each controlled by an electrical signal or the like by the controller 400. The valve 210V may be opened while the substrate 100 is processed with the etching gas and may be closed while the substrate 100 is not processed with the etching gas.

In some embodiments, the radical precursor may contain or include fluorine (F). For example, the radical precursor may contain or include at least one of NF₃, SiF₆, or CF₄.

In some embodiments, the etching gas provider 200 may include an inert gas provider 220 that provides the inert gas to the plasma formation space R1. The inert gas provider 220 may include a passage 220L through which the inert gas is provided to the plasma formation space R1. The inert gas provider 220 may include the pump so as to easily provide the inert gas to the plasma formation space R1, and the pump may apply pressure. Valves 220V may be between the passages 220L of the inert gas provider 220, and the operations of the pump and the valve 220V may be each controlled by an electrical signal or the like by the controller 400. The valve 220V may be opened while the substrate 100 is processed with the etching gas and may be closed while the substrate 100 is not processed with the etching gas.

In some embodiments, the inert gas provided from the inert gas provider 220 to the plasma formation space R1 may contain or include at least one of, for example, helium (He), neon (Ne), or argon (Ar).

In some embodiments, the etching gas provider 200 may create an environment so that the plasma may be formed in the plasma formation space R1 through the power supplier 230. The radical precursor provider 210 may provide the radical precursor to the plasma formation space R1, and the inert gas provider 220 may provide the inert gas to the plasma formation space R1. In this way, the radicals may be formed in the plasma formation space R1. The formed radicals may move to the distribution space R2 through the communicating space. The radicals existing in the distribution space R2 may be emitted in the direction toward the substrate processing space 110S through at least one hole 131H. At least some of the radicals emitted through at least one hole 131H may be recombined in a recombination space R3 adjacent to the distribution space R2 to form the recombination gas. The recombination space R3 may be a portion of the substrate processing space 110S. The operation of the etching gas provider 200 may be controlled by the controller 400.

In some embodiments, the radical precursor provider 210 may provide the radical precursor containing or including the fluorine (F) to the plasma forming space R1. In the plasma forming space R1, the radical precursor may be converted into the fluorine radicals (F*), and the fluorine radicals (F*) may move to the distribution space R2 through the communicating space. The fluorine radicals (F*) existing in the distribution space R2 may be emitted in the direction toward the substrate processing space 110S through at least one hole 131H, and at least some of the emitted fluorine radicals (F*) may be recombined in the recombination space R3 to form fluorine gas (F₂).

In some embodiments, the substrate processing apparatus 10 may include the processing gas provider 300 that provides a processing gas to the substrate processing space 110S. In some embodiments, the processing gas may contain or include fluorine (F). In some embodiments, the recombination gas and/or the processing gas may each independently contain or include fluorine (F).

In some embodiments, the processing gas provider 300 may include a passage 300L through which the processing gas is provided to the substrate processing space 100S. The passage 300L may be configured to provide the processing gas to the distribution space R2. The processing gas provider 300 may include the pump to easily provide the processing gas to the substrate processing space 100S, and the pump may apply pressure. The processing gas provider 300 may include valves 300V that are between the passages 300L, and the operations of the pump and the valve 300V may be each controlled by an electrical signal or the like by the controller 400. The valve 300V may be opened while the substrate 100 is being processed with the processing gas and may be closed while the substrate 100 is not being processed with the processing gas.

In some embodiments, the processing gas may contain or include at least one of fluorine gas (F₂) or germanium fluoride gas (GeF₄). When the processing gas provider 300 is operating, an etching byproduct BY may remain in the substrate processing space 110S.

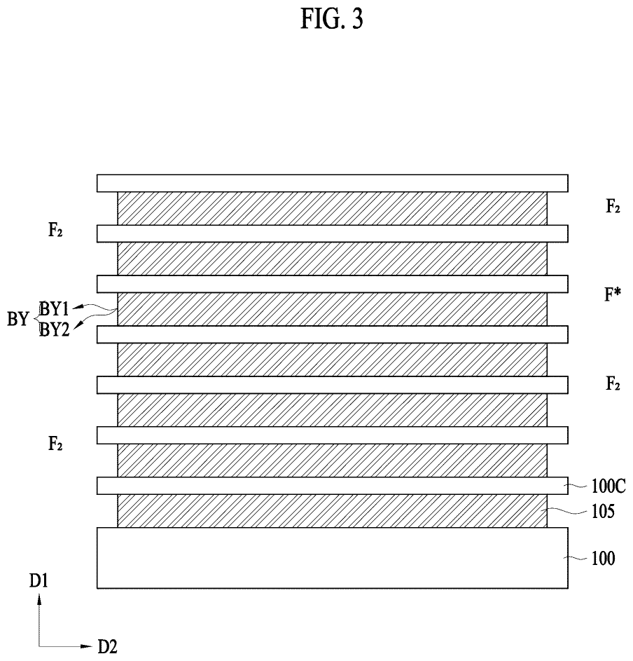

In some embodiments, the semiconductor layer 105, which is a sacrificial layer, may be etched by the processing gas, and may be further etched or etched more quickly by the etching byproduct BY (see FIG. 3) remaining in the substrate processing space 110S. In addition, as the semiconductor layer 105 is etched by the processing gas and the etching byproduct BY, additional etching byproduct BY is further generated, which may further improve the overall process speed.

In some embodiments, the substrate processing apparatus 10 may include the controller 400 that is configured to control the substrate processing apparatus 10 to perform a cycle of processing the substrate 100 with the etching gas to form the etching byproduct BY and processing the substrate 100 with the processing gas while the etching byproduct BY exists or is present in the substrate processing space 100S. In some embodiments, the controller 400 may be configured to control the performance of a cycle including at least a first step wherein the substrate 100 is processed with the etching gas to form the etching byproduct BY; and a second step wherein the substrate is processed with the processing gas while the etching byproduct BY exists or is present in substrate processing space 100S. In some embodiments, the controller 400 may be, but is not limited to, an electronic device that transmits and receives electronic signals and may be operated by a mechanical device or manually. In some embodiments, the controller 400 may be directly or indirectly connected to components included in the substrate processing apparatus 10 to control the operations of the components included in the substrate processing apparatus 10. Here, the direct connection may mean a connection that it is connected by contact through a wire or the like, and an indirect connection may mean a connection that it is connected without contact through wireless communication or the like. If necessary, the component connected to the controller 400 may include a transceiver for transmitting and receiving data in the form of an electronic signal. The controller 400 may also include a transceiver for transmitting and receiving data in the form of an electronic signal as another component. If necessary, the controller 400 may include a processor or processors configured to process an electronic signal.

In some embodiments, the controller 400 may be configured to control the substrate processing apparatus 10 to perform the cycle of processing the substrate 100 with the etching gas and processing the substrate 100 with the processing gas without performing the purge. In some embodiments, the controller 400 may be configured to control the performance of a cycle including at least a first step wherein of processing the substrate 100 is processed with the etching gas; and a second step wherein processing the substrate 100 is processed with the processing gas without performing a purge of the processing space 110S between the first and second steps. When the controller 400 controls the substrate processing apparatus 10 to process the substrate 100 with the etching gas, the etching byproduct BY may be formed. The controller 400 may be configured to control the substrate processing apparatus 10 to process the substrate 100 with the processing gas without separately purging the etching byproduct BY. In some embodiments, the controller 400 may be configured to control the performance of a process wherein the substrate 100 is processed with the etching gas (whereby the etching byproduct BY is formed) and thereafter a process wherein the substrate 100 is processed with the processing gas, without separately purging the etching byproduct BY from the processing chamber 110 before the processing with the processing gas. For example, the controller 400 may include a processor or processors configured to control the cycle.

In some embodiments, the controller 400 may first perform the etching using the radicals (i.e., processing the substrate 100 with the etching gas) and then perform the etching using the gas without purging the etching byproduct BY generated therefrom (i.e., processing the substrate 100 with the processing gas), so an etching area to be etched may be expanded, and the etching byproduct BY that helps the etching may be quickly generated, thereby increasing the etching selectivity and improving the overall process speed.

In some embodiments, the controller 400 may be configured to control the substrate processing apparatus 10 to process the substrate 100 with the etching gas for a first duration of time and to process the substrate with the processing gas for a second duration of time. In some embodiments, the first duration of time is shorter than the second duration of time. As a result, it is possible to improve the overall process speed while increasing the etching selectivity. For example, the controller 400 may include a processor or processors configured to control a time required to process the substrate.

In some embodiments, the controller 400 may stop the operation of the etching gas provider 200 when operating the processing gas provider 300. The processing gas provider 300 may provide the processing gas to the substrate processing space 110S. The operation of the processing gas provider 300 may be controlled by the controller 400.

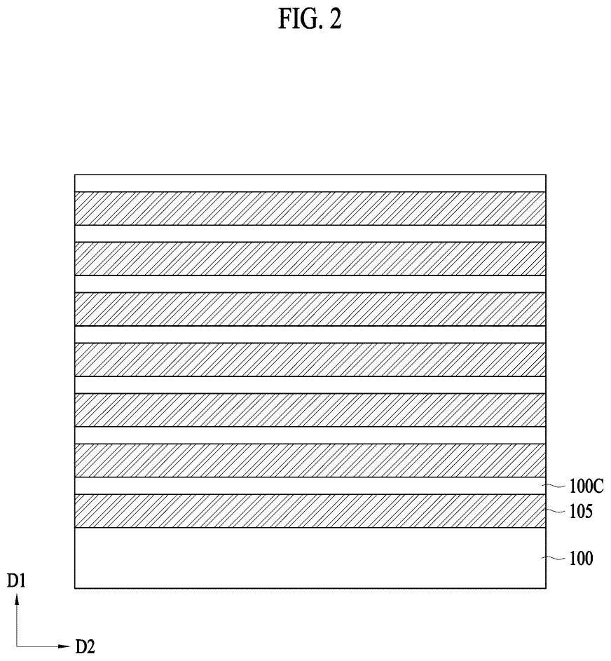

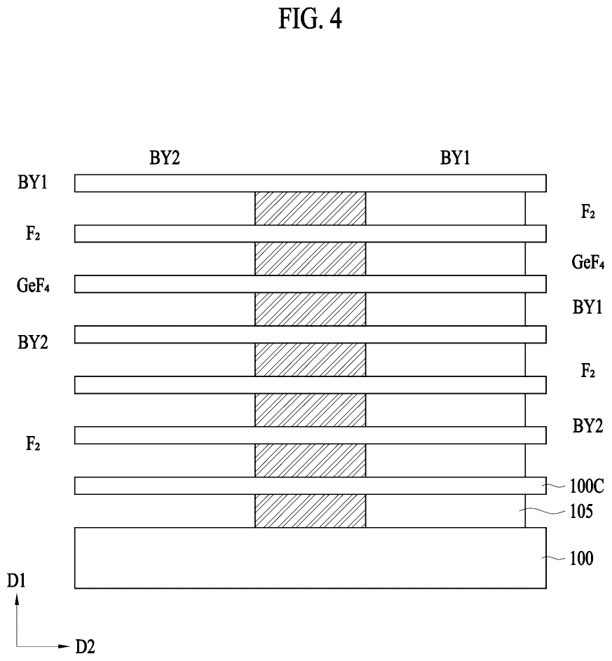

FIGS. 2 to 4 are cross-sectional views schematically illustrating the substrate 100 and the semiconductor layer 105 for describing a process of processing the substrate 100 by the substrate processing apparatus 10 according to some embodiments of the present disclosure.

In some embodiments, the substrate processing apparatus 10 may etch at least a portion of the semiconductor layer 105 that is on the substrate 100 and contains or includes a compound semiconductor. In some embodiments, the semiconductor layer 105, which is the sacrificial layer, may be formed on the substrate 100, a channel layer 100C may be formed on the semiconductor layer 105, and the semiconductor layer 105 and the channel layer 100C may have a structure in which they are alternately stacked. In other words, the formed structure may include a plurality of semiconductor layers 105 and a plurality of channel layers 100C. The plurality of semiconductor layers 105 and the plurality of channel layers 100C may be arranged such that they are stacked on the substrate 100 in the vertical direction D1 and may be arranged such that they repeatedly alternate one semiconductor layer 105 then one channel layer 100C. In some embodiments, the channel layer 100C may contain or include silicon (Si).

In some embodiments, the etching byproduct BY may be formed while the etching gas etches the semiconductor layer 105. In some embodiments, the compound semiconductor may contain or include a first element and a second element different from each other. Each of the first element and the second element may be independently a group III element, a group IV element, or a group V element. The group III elements may be one of group 3 elements and group 13 elements of the periodic table, the group IV elements may be one of group 4 elements and group 14 elements of the periodic table, and the group V element may be one of group 5 elements and group 15 elements of the periodic table. The group III element may be, for example, one of boron (B), aluminum (Al), gallium (Ga), or indium (In). The group IV element may be, for example, one of silicon (Si), germanium (Ge), or tin (Sn). The group V element may be, for example, one of phosphorus (P) or arsenic (As).

In some embodiments, the first element may be the group IV element and the second element may be the group IV element different from the first element. The first element may have fewer protons than the second element. For example, the first element may be silicon (Si) and the second element may be germanium (Ge). In some embodiments, the semiconductor layer 105 may include silicon germanium (SiGe).

In some embodiments, the etching byproduct BY may include fluoride BY1 containing or including the first element and fluoride BY2 containing or including the second element. In some embodiments, the fluoride BY1 containing or including the first element and the fluoride BY2 containing or including the second element may be in a gaseous state at room temperature and atmospheric pressure.

In some embodiments, the processing gas may include at least one of fluorine gas (F₂) or fluoride containing or including the second element. The fluoride containing or including the second element may contain or include, for example, germanium fluoride gas (GeF₄). In some embodiments, the processing gas may contain or include at least one of fluorine gas (F₂) or germanium fluoride gas (GeF₄). In some embodiments, the fluoride containing or including the first element may contain or include, for example, silicon fluoride gas (SiF₄).

In some embodiments, the fluoride BY1 containing or including the first element may minimize or reduce the etching of the channel layer 100C. For example, the fluoride BY1 containing or including the first element may contain or include silicon fluoride gas (SiF₄), and the silicon fluoride gas (SiF₄) may protect the channel layer 100C from a material that may etch the channel layer 100C, such as fluorine gas (F₂) or germanium fluoride gas (GeF₄).

In some embodiments, the fluoride BY2 containing or including the second element may etch the semiconductor layer 105 or promote the etching of the semiconductor layer 105. For example, the fluoride BY2 containing or including the second element may contain or include germanium fluoride gas (GeF₄), and the germanium fluoride gas (GeF₄) may etch the semiconductor layer 105 like the fluorine gas (F₂) and promote the etching of the semiconductor layer 105.

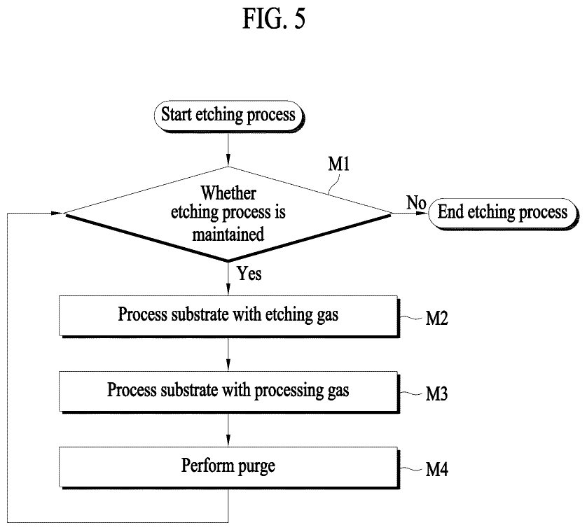

FIG. 5 is a flowchart for describing a method of performing a process of processing the substrate processing apparatus 10 according to some embodiments of the present disclosure.

In some embodiments, the controller 400 may be configured to control the substrate processing apparatus 10 to perform the cycle multiple times. In other words, the controller 400 may control the performance of multiple cycles of processing the substrate 100. In some embodiments, the controller 400 may determine whether to maintain the etching process (Step M1), and if so, may control the substrate processing apparatus 10 to process the substrate 100 with the etching gas (Step M2) and then process the substrate 100 with the processing gas (Step M3) without performing the purge between the etching gas step (Step M1) and the processing gas step (Step M3). For example, the controller 400 may include a processor or processors configured to control the number of the cycle. The controller 400 may then, after the step of processing the substrate 100 with the processing gas (Step M3), control the substrate processing apparatus 10 to purge the chamber 110 (Step M4).

In some embodiments, the controller 400 may stop the operation of the purger 140 when the etching gas provider 200 or the processing gas provider 300 is operating (Steps M2 or M3). In some embodiments, the controller 400 may stop the operations of the etching gas provider 200 and the processing gas provider 300 when the purger 140 is operating (Step M4).

In some embodiments, the controller 400 may control the substrate processing apparatus 10 to perform the purge during at least some of the cycles. In other words, the controller 400 may be configured to control the performance of the purge during at least some of the cycles. In some embodiments, the controller 400 may determine whether to maintain the etching process, and if so, may control the substrate processing apparatus 10 to process the substrate 100 with the etching gas, process the substrate 100 with the processing gas without performing the purge, and then perform the purge. By controlling the substrate processing apparatus 10 to perform the purge during at least some of the cycles, it is possible to minimize or reduce the non-uniform etching of the semiconductor layer 105, which is the sacrificial layer, due to the continuous accumulation of the etching byproduct BY. In particular, by controlling the substrate processing apparatus 10 to perform the purge during at least some of the cycles, when the semiconductor layer 105 is a multilayer film, for example, a multilayer film of 10-stage or more, it is possible to minimize or reduce the difference in the etching degree between the upper and lower portions.

Example embodiments of the present disclosure have been described hereinabove with reference to the accompanying drawings, but the present disclosure is not limited to the above-described example embodiments, and may be implemented in various different forms, and one of ordinary skill in the art to which the present disclosure pertains may understand that the present disclosure may be implemented in other specific forms without changing the technical spirit or essential features of the present disclosure. Therefore, it is to be understood that the example embodiments described above are illustrative rather than being restrictive in all aspects.

What is claimed is:

1. A substrate processing apparatus, comprising:
a chamber including a substrate processing space;
a supporter inside the chamber and configured to support a substrate;
an etching gas provider configured to provide an etching gas to the substrate processing space, wherein the etching gas includes radicals and/or a recombination gas formed by recombining radicals;
a processing gas provider configured to provide a processing gas to the substrate processing space; and
a controller configured to control the substrate processing apparatus to perform a cycle including:
processing the substrate with the etching gas to form an etching byproduct; and
processing the substrate with the processing gas while the etching byproduct is present in the substrate processing space.

2. The substrate processing apparatus of claim 1, wherein the recombination gas and the processing gas each independently include fluorine (F).

3. The substrate processing apparatus of claim 2, wherein a semiconductor layer including a compound semiconductor is on the substrate, and
the etching byproduct is formed when the etching gas etches the semiconductor layer.

4. The substrate processing apparatus of claim 3, wherein the compound semiconductor includes a first element and a second element different from each other, and
each of the first element and the second element is independently a group III element, a group IV element, or a group V element.

5. The substrate processing apparatus of claim 4, wherein the etching byproduct includes a fluoride including the first element and a fluoride including the second element.

6. The substrate processing apparatus of claim 5, wherein the fluoride including the first element and the fluoride including the second element are in a gaseous state at room temperature and atmospheric pressure.

7. The substrate processing apparatus of claim 5, wherein the first element has fewer protons than the second element.

8. The substrate processing apparatus of claim 7, wherein the recombination gas includes fluorine gas (F₂), and
wherein the processing gas includes at least one of fluorine gas (F₂) or the fluoride including the second element.

9. The substrate processing apparatus of claim 1, wherein the controller is configured to control the substrate processing apparatus to process the substrate with the etching gas for a first duration of time and to process the substrate with the processing gas for a second duration of time,
wherein the first duration of time is shorter than the second duration of time.

10. The substrate processing apparatus of claim 1, wherein the controller is configured to control the substrate processing apparatus to perform the cycle multiple times.

11. The substrate processing apparatus of claim 10, wherein the controller is configured to control the substrate processing apparatus to perform a purge during at least some of the cycles.

12. The substrate processing apparatus of claim 1, wherein the etching gas provider includes a plasma forming space where the radicals are formed, a power supplier configured to form plasma in the plasma forming space, and a radical precursor provider configured to provide a radical precursor to the plasma forming space.

13. The substrate processing apparatus of claim 12, wherein the radical precursor includes at least one of NF₃, SiF₆, or CF₄.

14. The substrate processing apparatus of claim 12, wherein the etching gas provider further includes an inert gas provider configured to provide an inert gas to the plasma forming space.

15. The substrate processing apparatus of claim 1, further comprising a shower head including a first plate in which at least one hole communicating with the substrate processing space is formed and a second plate,
wherein the first plate and the second plate together form a distribution space.

16. The substrate processing apparatus of claim 15, wherein the shower head is inside the chamber, spaced apart from the substrate in a first direction perpendicular to a surface of the substrate.

17. A substrate processing apparatus, comprising:
a chamber including a substrate processing space;
a supporter inside the chamber and configured to support a substrate;
an etching gas provider configured to provide an etching gas to the substrate processing space, wherein the etching gas includes radicals, and/or a recombination gas formed by recombining radicals;
a processing gas provider configured to provide a processing gas to the substrate processing space; and
a controller configured to control the substrate processing apparatus to perform a cycle including:
processing the substrate with the etching gas; and
processing the substrate with the processing gas without performing a purge between the steps of processing the substrate with the etching gas and processing the substrate with the processing gas.

18. The substrate processing apparatus of claim 17, wherein a semiconductor layer including silicon germanium (SiGe) is on the substrate,
the radicals include fluorine radicals (F*) and the recombination gas includes fluorine gas (F₂), and
the processing gas includes at least one of fluorine gas (F₂) or germanium fluoride gas (GeF₄).

19. The substrate processing apparatus of claim 17, wherein the controller is configured to control the substrate processing apparatus to:
process the substrate with the etching gas for a first duration of time and to process the substrate with the processing gas for a second duration of time, wherein the first duration of time is shorter than the second duration of time;
perform the cycle on the substrate multiple times; and
perform a purge during at least some of the cycles.

20. A substrate processing apparatus, comprising:
a chamber including a substrate processing space;
a supporter inside the chamber and configured to support a substrate;
an etching gas provider configured to provide an etching gas to the substrate processing space, wherein the etching gas includes radicals and/or a recombination gas formed by recombining the radicals;
a processing gas provider configured to provide a processing gas to the substrate processing space; and
a controller configured to control the substrate processing apparatus to perform a cycle including:
processing the substrate with the etching gas to form an etching byproduct; and
processing the substrate with the processing gas while the etching byproduct is present in the substrate processing space;
wherein:
the etching gas provider includes:
a plasma forming space where the radicals are formed;
a power supplier configured to form plasma in the plasma forming space; and
a radical precursor provider configured to provide a radical precursor to the plasma forming space;
a semiconductor layer including silicon germanium (SiGe) is on the substrate;
the radicals include fluorine radicals (F*);
the recombination gas includes a fluorine gas (F₂);
the processing gas includes at least one of fluorine gas (F₂) or germanium fluoride gas (GeF₄); and
the controller is configured to control the substrate processing apparatus to:
process the substrate with the etching gas for a first duration of time and to process the substrate with the processing gas for a second duration of time, wherein the first duration of time is shorter than the second duration of time;
perform the cycle on the substrate multiple times; and
perform a purge during at least some of the cycles.
